(19) United States
(12) Patent Application Publication
(10) Pub. No.: US 2023/0096301 A1
(43) Pub. Date: Mar. 30, 2023

(54) Circuit Board Traces in Channels using Electroless and Electroplated Depositions

(71) Applicant: CATLAM, LLC., Sunnyvale, CA (US)

(72) Inventors: Kenneth S. BAHL, Saratoga, CA (US); Steven CARNEY, San Jose, CA (US); Jagdip SINGH, Fremont, CA (US); Steven DUTTON, Phoenix, AZ (US)

(73) Assignee: CATLAM, LLC., Sunnyvale, CA (US)

(21) Appl. No.: 17/489,622

(22) Filed: Sep. 29, 2021

(51) Int. Cl. H05K 3/18; H05K 3/42; C23C 18/16; C25D 5/02

(52) U.S. Cl. CPC H05K 3/185; H05K 3/423; C23C 18/1653; C25D 5/022

(57) ABSTRACT

A circuit layer is formed by drilling vias and forming channels in a circuit layer which has catalytic particles exposed on the surfaces, channels, and vias. A first flash electroless deposition is followed by application of dry film, followed by selective laser ablation of the dry film channels and vias. A second electroless solution is applied which provides additional deposition over the first flash electroless deposition but only on the vias and trace channel areas. An electrodeposition follows, using the first deposition as a cathode. The dry film is stripped and the first electroless layer is etched, leaving only depositions in the channels and vias.

### FIELD OF THE INVENTION

The present invention relates to a catalytic laminate and its uses in circuit board fabrication. In particular, the laminate has surface properties which provide for fine pitch circuit interconnects which can be formed in channels to form circuit board layers having planar surfaces with embedded conductors.

### BACKGROUND OF THE INVENTION

Prior art printed circuit boards (PCB) are formed using conductive metal interconnects (known as “traces”) formed on a dielectric substrate, where each surface carrying conductors is known as a “layer”. Each dielectric core has traces formed on one surface or on both surfaces, and by stacking several such dielectric cores having traces formed in them interspersed with bare dielectric layers, and laminating them together under temperature and pressure, a multi-layer printed circuit may be formed. The dielectric substrate comprises an epoxy resin embedded in a fiber matrix such as glass fiber woven into a cloth. In one prior art fabrication method, copper is laminated onto the outer surfaces of a dielectric layer, the copper surfaces are patterned such as with a photoresist or photo sensitive film to create masked and unmasked regions, and then etched to form a conductive trace layer on one or both sides of the core dielectric. A stack of dielectric cores with conductive traces may then be laminated together to form multi-layer boards, and any layer interconnects made with vias, which are drilled holes plated with copper to form annular rings which provide connectivity from one layer to another.

Printed circuit boards (PCB) are typically used to provide conductive traces between various electronic components mounted on the PCB. One type of electronic component is a through-hole device which is mounted on the PCB by having leads positioned through one or more holes in the PCB, where the PCB hole includes a conductive annular ring pad on each trace connect layer, and the component lead is soldered to the annular ring pad of the PCB hole. Through hole components have leads which tend to be difficult to align with the associated PCB mounting hole, but surface mount technology (SMT) provides a preferable mounting system, where component leads are simply placed on the surface of a PCB pad and soldered, which is preferred for PCB assembly because of the higher density and ease of mechanized assembly. Surface mount components require only surface mount pads on an outside finished PCB layer. Within a two layer or multi-layer PCB, interconnects of conductive traces from one layer to another are accomplished using through-hole vias, where a conductive trace on one trace layer leads to a hole which is typically drilled through one or more dielectric layers of the PCB and plated with copper or other conductive metal to complete the trace layer connection. A hole drilled through all dielectric layers is known as a thru-via, a hole drilled through an outer layer only (typically as part of the fabrication of the individual layer) is known as a micro-via, and a hole drilled through one or more inner layers is known as a blind via. For any of these via types, the via is patterned to include an annular ring conductor region on opposite trace layers of the PCB, with the drilled hole lined with conductive material which connects the annular ring conductors on either side of the laminate or PCB.

When a continuous layer of copper is present that may be used as a cathode electrode, the thickness of pre-patterned or post-patterned copper on a printed circuit board laminate may be increased using electroplating, where the PCB or dielectric layer with traces is placed in an electrolytic bath, and a DC source is connected between a sacrificial anodic conductor (such as a copper rod) to an existing conductive layer of a PCB.

Where a pre-existing conductive copper layer is not present on a PCB, an electroless process with the assistance of a “seed” catalytic material (which enhances the deposition of a particular conductive material) is deposited on the surface of the dielectric, and the board is then placed in an electroless bath. For a catalyst such as palladium and an electroless bath of copper, the copper ions in solution deposit over the palladium until the surface is covered sufficiently to provide sufficient electrical conductivity. Electroplating is preferred, as it has a faster deposition rate than the electroless plating process. Electroless plating also has the disadvantage that the conductivity of the deposition is lower, as the grain structure of the deposition is loosely consolidated, leading to higher trace resistance.

As electronic assemblies increase in complexity, it is desired to increase component densities on PCB assemblies, such as by using smaller trace widths (known as fine pitch traces) in conjunction with increasingly dense integrated circuit (IC) lead patterns. One problem of prior art surface mount PCB fabrication and assembly methods is that because the traces are formed on the surface of the dielectric, the adhesion between copper trace and underlying laminate for narrower conductor line widths (known as fine pitch traces) is reduced, causing the fine pitch traces and component pads to separate (lift) during a component replacement operation, ruining the entire circuit board assembly and expensive components on it. Another problem of fine pitch surface traces is that when fabricating a multi-layer circuit board, the individual trace layers are laminated together under pressure in an elevated temperature environment. During lamination, fine pitch traces tend to migrate laterally across the surface of the dielectric. In high speed circuit design, it is desired to maintain a fixed impedance between traces, particularly for differential pair (edge coupled) transmission lines. This lateral migration of traces during lamination causes the transmission line impedance of the finished PCB differential pair to vary over the length of the trace, which causes reflections and losses in the transmission line compared to one with fixed impedance characteristics resulting from constant spacing.

It is desired to provide a printed circuit board pre-preg and trace forming processes which provide trace positions which remain stationary during the lamination process. It is desired to provide low resistance traces such as by electrolytic deposition in an additive process which forms traces. It is also desired to provide dielectric and trace layers with finished planar surfaces to prevent lateral forces on traces from developing during lamination. It is also desired to provide a method and apparatus for forming fine pitch circuit boards using catalytic and non-catalytic pre-preg for use in printed circuit processing.

### OBJECTS OF THE INVENTION

A first object of the invention is a process for making a circuit board laminate from catalytic material having catalytic particles present on the surface or an exclusion depth below the surface, the process comprising drilling through holes and forming channels into the catalytic material to a depth below the exclusion depth on one surface or both surfaces, thereafter optionally performing a blanket etch over the one or both surfaces so that catalytic particles are exposed on the one surface or both surfaces, thereafter performing a flash electroless deposition with a first electroless solution having self-limiting deposition properties, optionally performing a second electroless deposition using a second electroless solution, thereafter applying and curing a photoresist such as dry film to the one surface or both surfaces, thereafter patterning the dry film to expose areas where channels were formed, thereafter optionally performing a second electroless deposition if not previously performed, the second electroless solution not having self-limiting deposition properties, thereafter performing an electrodeposition using the first and/or second electroless deposition as a cathode electrode, thereafter stripping the dry film, and finally etching the flash electroless deposition applied by the first electroless solution.

A second object of the invention is a process for making a circuit board laminate from non-catalytic material, the process comprising drilling through holes and forming channels into the catalytic material, thereafter performing a surface treatment with a catalytic material to provide catalytic particles on one or both surfaces, thereafter performing a flash electroless deposition with a first electroless solution having self-limiting deposition properties and thereafter optionally performing a second electroless deposition with a second electroless solution, thereafter applying and patterning a photoresist such as dry film to the one surface or both surfaces, dry film patterned to exclusively expose areas where channels were formed, thereafter optionally performing a second electroless deposition with a second electroless solution not having self-limiting deposition properties if the second electroless deposition was not previously performed, thereafter performing an electrodeposition using the first and/or second electroless deposition as a cathode electrode, thereafter stripping the dry film, and finally etching the flash electroless deposition applied by the first electroless solution.

A third object of the invention is a process for forming a circuit layer with traces on a laminate, the process comprising:

drilling through vias on at least one surface of the laminate;

performing a surface treatment providing a catalytic surface on the vias and the at least one surface of the laminate;

providing a first electroless deposition on the inner surfaces of the through vias and the surface of the laminate;

applying a photoresist to the surface of the laminate, the photo resist also covering the through vias;

ablating the photoresist in areas above the through vias;

ablating channels into the laminate; applying a surface catalyst to the channels of the laminate;

providing a second electroless deposition to exposed channels and exposed vias;

performing an electro deposition to the exposed channels and exposed vias after connecting the first electroless deposition to a cathode electrode in an electro deposition bath;

stripping the dry film;

etching exposed flash electroless deposition.

### SUMMARY OF THE INVENTION

The present invention is a process and apparatus related to manufacturing a printed circuit board (PCB) laminate that may be used to form a single layer or multi-layer laminate from either a catalytic or non-catalytic laminate.

In a first example of the invention, the catalytic laminate has uniformly distributed catalytic particles which are present below an exclusion depth from the surface of the catalytic laminate. The catalytic laminate has any required through holes drilled and channels formed which extend below the surface and into the catalytic particles below the exclusion depth. The channels may be formed on one side or both sides of the catalytic laminate. A blanket plasma etch is performed to expose catalytic particles on the outer surfaces of the catalytic laminate. A first flash electroless deposition is performed using a first electroless solution to provide a flash layer of conductive metal such as copper which uniformly covers the surfaces, through holes, and channels, the flash electroless deposition having sufficient thickness to support subsequent electroplating deposition of a later step. An optional second electroless deposition may be subsequently performed using a second electroless plating solution. Next, a photoresist such as dry film is applied and patterned to expose the channels and through holes. If not previously performed, an optional second electroless deposition may be performed which deposits on the exposed channels and holes only. A subsequent electroplating step results in a deposition on the exposed channels and through holes or vias, the electroplating using the first flash electroless deposition or second electroless deposition as a cathode electrode, such that the channels and vias receive a durable, well-bonded electrodeposition in the through holes and channels, which fill with electroplated metal. The dry film is subsequently stripped, after which an etch is performed sufficient to remove the flash electroless plating of the first flash electroless deposition step.

In a variation of the first example of the invention, the catalytic laminate may have a catalytic particle exclusion depth of 0, such that catalytic particles are exposed at the surface of the catalytic laminate. In this case, the previously described blanket plasma etch to expose catalytic particles on the outer surfaces of the catalytic laminate bay is unnecessary, and the other steps performed as previously described.

In another variation of the invention, the second electroless deposition is performed uniformly over the surface before the surface is patterned with resist such that the second electroless deposition covers the first electroless deposition on the surface and channels prior to application of resist such a dry film.

In another variation of the invention, the second electroless deposition is performed after the surface is patterned with resist such as dry film, such that the second electroless deposition occurs only in the exposed channels and holes that are exposed by the patterning.

In a second example of the invention, the laminate does not have catalytic particles, and may be referred to as a non-catalytic laminate. The non-catalytic laminate has any required through holes drilled and channels formed which extend below the surface. The channels may be formed on one side or both sides of the laminate. A surface catalytic treatment is performed which provides catalytic particles or catalytic surface deposition. A first flash electroless deposition is performed to provide a flash layer of conductive metal such as copper which is attracted to the catalyst and so uniformly covers the surfaces, through holes, and channels, the flash electroless deposition having sufficient thickness to support subsequent electroplating deposition of a later step. Optionally, a second electroless deposition may follow using a second electroless solution which increases the deposition thickness of the first flash electroless deposition. Next, a photoresist such as dry film is applied and patterned to expose the channels and through holes. Electroplating occurs next, using the first and/or second flash deposition as a cathode electrode, and the channels and vias receive a durable, well-bonded electrodeposition in the through holes and channels, which fill with electroplated metal. The dry film is subsequently stripped, after which an etch is performed sufficient to remove the flash electroless plating of the first flash electroless deposition step.

In a third example of the invention, the vias (or through holes) are formed on at least one surface of a non-catalytic laminate, followed by a surface treatment providing catalytic surfaces on the laminate surfaces and vias (or through holes) followed by a flash electroless deposition using an electroless deposition solution operative to deposit metal on the catalytic surfaces. The electroless deposition may be a first solution with a self-limit for deposition, and the flash electroless deposition provides a metal deposition on the inner surfaces of the through vias, the channels, and the surfaces. Alternatively, the flash electroless deposition may be achieved using a foil-coated laminate which has via or through holes drilled, coated with a catalytic surface treatment and the via or through holes electroless plated to reach the same point in the process. For either approach, a photoresist is subsequently applied to the surfaces of the laminate, the photoresist also covering the through vias, and the photoresist is ablated in areas above the through vias to remove the photoresist in these areas, and a higher power ablation is also performed with a power level sufficient to not only ablate the photoresist but also form channels in the laminate. A subsequent catalytic treatment of the exposed channels and vias is performed, followed by electroless deposition in the exposed areas, thereby completing a flash surface conductor comprising the conductive deposition below the photoresist, and the electroless deposition in the channels. In this manner, the electroless deposition provides a cathodic electrode for electroplating, performing an electro deposition by connecting the electrically continuous surface of the laminate as a cathode in an electroplating bath, where the only electroplating occurs in the exposed channels and exposed vias, after which the dry film is stripped and the exposed flash electroless deposition is stripped. The remaining conductors formed by durable electroplated deposition in the channels provide a low electrical conductivity and form the traces, vias, and through holes of a printed circuit board.

### BRIEF DESCRIPTION OF THE DRAWINGS

FIG. 1A shows a schematic view of a process for forming a raw catalytic pre-preg.

FIG. 1B shows a vacuum lamination press for forming a finished catalytic pre-preg from a raw catalytic pre-preg.

FIG. 1C shows a vacuum lamination stage to for forming multiple layers of catalytic pre-preg during a lamination.

FIG. 2 shows processing times for a vacuum lamination step of FIG. 1.

FIG. 3 shows process steps for formation of a catalytic pre-preg.

FIG. 4 shows a plot of catalytic particle distribution in a pre-preg material with respect to a section view of the pre-preg material.

FIG. 5A-1 shows a section view of native catalytic pre-preg.

FIG. 5B-1 shows a section view of catalytic pre-preg after forming a via/through hole and channel.

FIG. 5C-1 shows a section view of catalytic pre-preg after a surface blanket etch.

FIG. 5D shows a section view of catalytic pre-preg after a flash electroless deposition in a first solution.

FIG. 5E shows a section view of catalytic pre-preg after application of dry film.

FIG. 5F shows a section view of catalytic pre-preg after patterned ablation of dry film.

FIG. 5G shows a section view of catalytic pre-preg after a high build electroless deposition in a second solution.

FIG. 5H shows a section view of catalytic pre-preg after electro deposition with the flash electroless and high build electroless deposition used as a cathode electrode.

FIG. 5I shows a section view of catalytic pre-preg after stripping the patterned dry film.

FIG. 5J shows a section view of catalytic pre-preg after blanket etching the flash electroless deposition.

FIG. 6 shows a process flowchart for a catalytic laminate.

FIG. 7 shows a process flowchart for a non-catalytic laminate.

FIGS. 8A and 8B show a process flowchart which includes certain variations of the process.

FIG. 9A shows a process flowchart for making a circuit board using a standard (non-catalytic) laminate with a foil surface and a single channel-forming and patterning step.

FIG. 9B shows a process flowchart for making a circuit board from a standard dielectric with no foil surface and a single channel-forming and patterning step.

FIGS. 10A through 10D show cross section views of a sequence of process steps for forming a conductor in a channel.

FIG. 10E shows a cross section view of a conductor in a channel.

FIGS. 10E-1 and 10E-2 are cross section views of a conductor in a channel of FIG. 10E-3.

### DETAILED DESCRIPTION OF THE INVENTION

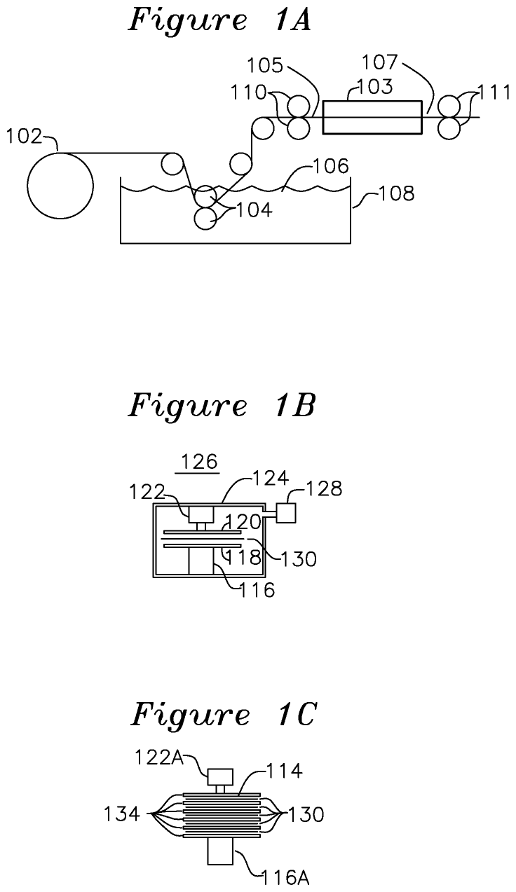

FIG. 1A shows an example process for fabricating pre-preg (a matrix of pre-impregnated fibers bound in resin). Many different materials may be used for the fibers of pre-preg, including woven glass-fiber cloth, carbon-fiber, or other fibers, and a variety of different materials may be used for the resin, including epoxy resin, polyimide resin, cyanate ester resin, PTFE (Teflon) blend resin, or other resins. One aspect of the invention is a printed circuit board laminate capable of supporting fine pitch conductive traces on the order of 1 mil (25 u), and while the description is drawn to the formation of copper traces using catalysts for electroless copper formation, it is understood that the scope of the invention may be extended to other metals suitable for electroless plating and electro-plating. For electroless deposition of copper (Cu) channels, elemental palladium (Pd) is preferred as the catalyst, although selected periodic table transition metal elements, such as group 9 to 11 platinum (Pt), rhodium (Rh), iridium (Ir), nickel (Ni), gold (Au), silver (Ag), cobalt (Co), or copper (Cu), or other compounds of these, including other metals such as iron (Fe), manganese (Mn), chromium (Cr), molybdenum (Mo), tungsten (W), titanium (Ti), tin (Sn), or mixtures or salts of the above, any of which may be used as catalytic particles. The present candidate list is intended to be exemplar rather than comprehensive, it is known in the art that other catalysts for attracting copper ions may also be used. In one example of the invention, the catalytic particles are homogeneous catalytic particles. In another example of the invention, the catalytic particles are inorganic particles or high temperature resistant plastic particles which are coated with a few angstrom thickness of catalytic metal, thereby forming heterogeneous catalytic particles having a thin catalytic outer surface encapsulating a non-catalytic inner particle. This formulation may be desirable for larger catalytic particles, such as those on the order of 25 u in longest dimension. The heterogeneous catalytic particle of this formulation can comprise an inorganic, organic, or inert filler such as silicon dioxide (SiO₂), an inorganic clay such as Kaolin, or a high temperature plastic filler coated on the surface with a catalyst such as palladium adsorbed onto the surface of the filler, such as by vapor deposition or chemical deposition. Only a few atomic layers of catalyst are required for the catalytic particle to have desirable properties conducive to electroless plating.

In one example of forming heterogeneous catalytic particles, a bath of fillers (organic or inorganic) is sorted by size to include particles less than 25 u in size, these sorted inorganic particles are mixed into an aqueous bath in a tank, agitated, and then a palladium salt such as PdCl (or any other catalyst such as a salt of silver of other catalyst) is introduced with an acid such as HCl, and with a reducing agent such as hydrazine hydrate, the mixture thereby reducing metallic Pd which coats the inorganic particles provide a few angstroms of thickness of Pd coated on the filler, thereby creating a heterogeneous catalytic particle which has the catalytic property of a homogeneous Pd particle with a greatly reduced volume requirement of Pd compared to using homogeneous Pd metallic particles. For extremely small catalytic particles on the order of a few nm, however, homogeneous catalytic particles (such as pure Pd) may be preferred.

Example inorganic fillers include clay minerals such as hydrous aluminum phyllosilicates, which may contain variable amounts of iron, magnesium, alkali metals, alkaline earths, and other cations. This family of example inorganic fillers includes silicon dioxide, aluminum silicate, kaolinite (Al₂Si₂O₅(OH)₄), polysilicate, or other clay minerals which belong to the kaolin or china clay family. Example organic fillers include PTFE (Teflon) and other polymers with high temperature resistance.

Examples of palladium salts are: BrPd, CL₂Pd, Pd(CN)₂, I₂Pd, Pd (NO₃)₂*2H₂O, Pd(NO₃)₂, PdSO₄, Pd (NH₃)4Br₂, Pd(NH₃)4Cl₂H₂O. The catalytic powder of the present invention may also contain a mixture of heterogeneous catalytic particles (for example, catalytic materials coated over inorganic filler particles), homogeneous catalytic particles (such as elemental palladium), as well as non-catalytic particles (selected from the family of inorganic fillers).

Among the catalysts, palladium is a preferred catalyst because of comparative economy, availability, and mechanical properties, but other catalysts may be used.

FIG. 1A shows a roll of fabric cloth 102 such as woven glass fiber is fed through as set of rollers which guide the fabric into tank 108 which is filled with an epoxy resin blended with catalytic particles and mixed with a volatile liquid to reduce the viscosity, thereby forming an A-stage (liquid) pre-preg.

The resin may be a polyimide resin, a blend of epoxy and cyanide ester (which provides curing at elevated temperatures), or any other suitable resin formulation with selectable viscosity during coating and thermosetting properties after cooling. Fire retardants may be added, for example to comply with a flammability standard, or to be compatible with one of the standard FR series of pre-preg such as FR-4 or FR-10. An additional requirement for high speed electrical circuits is dielectric constant ε (permittivity), which is often approximately 4 and governs the characteristic impedance of a transmission line formed on the dielectric, and loss tangent δ, which is measure of frequency-dependent energy absorption over a distance, whereby the loss tangent is a measure of how the dielectric interacts with high frequency electric fields to undesirably reduce signal amplitude by a calculable amount of dB per cm of transmission line length. The resin is blended with catalytic particles which have been sorted for size. In one example formulation, the catalytic particles include at least one of: homogeneous catalytic particles (metallic palladium), or heterogeneous catalytic particles (palladium coated over an inorganic particle or high temperature plastic), and for either formulation, the catalytic particles preferably having a maximum extent of less than 25 u and with 50% of the particles by count sized between 12 u and 25 u, or the range 1-25 u, or smaller. These are example catalytic particle size embodiments not intended to limit the scope of the invention. In one example embodiment, the catalytic particles (either homogeneous or heterogeneous) are in the size range 1 u-25 u. In another example of the invention, homogeneous catalytic particles are formed by grinding metallic palladium into particles and passing the resultant particles through a sieve with a mesh having 25 u rectangular openings. In another example, the catalytic resin mixture 106 is formed by blending homogeneous or heterogeneous catalytic particles into the pre-preg resin by a ratio of weights, such as the ratio of substantially 12% catalytic particles by weight to the weight of resin. The ratio by weight of catalytic particles in the resin mixture may alternatively be in the range of 8-16% of catalytic particle weight to the total weight of resin. It is understood that other blending ratios may also be used, and it may be preferable to use smaller particles. In one example of the invention, the catalytic particle density is chosen to provide a mean distance between catalytic particles on the order of 3 u-5 u.

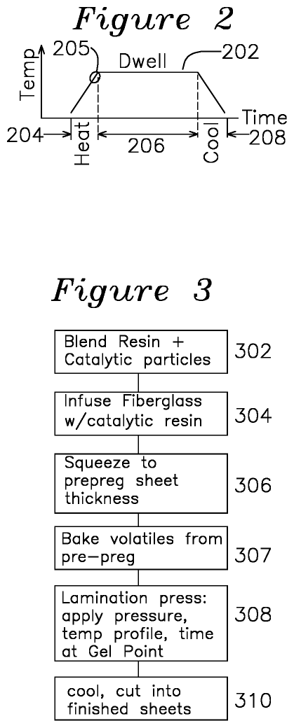

After the fabric is immersed into the catalytic resin bath 106 with rollers 104, the catalytic resin impregnated cloth is guided to rollers 110, which establish the thickness of the uncured liquid A-stage pre-preg 105 which also establishes the percentage of resin in the resin/glass+resin ratio. The A-stage pre-preg 105 is then passed through a baking oven 103 which drives out the organics and other volatile compounds of the A-stage pre-preg and greatly reduces the liquid content, forming tack-free B-stage pre-preg 107 delivered by rollers 111. In an example embodiment, oven 103 dries the volatile compounds from an about 80% solvent ratio of A-stage pre-preg to less than about 0.1% solvent ratio for B-stage pre-preg. The resulting B-stage pre-preg 107 is provided to material handling 111 and can be cut into sheets for ease of handling and storage, and is later placed into the lamination press 126 of FIG. 1B which applies pressure across the surface of the sheets under vacuum, changing the temperature profile while the pre-preg core is in the lamination press, following the temperature plot 202 shown in FIG. 2. In one example of the invention, to create the resin rich surface, the pre-preg sheets positioned near the outer surfaces (which will later have the surface removed to expose the underlying catalytic particles) are selected to have greater than 65% resin, such as Glass 106 (71% resin), Glass 1067, or Glass 1035 (65% resin), and the inner pre-preg sheets (which are not subject to surface removal) are selected to have less than 65% resin. Additionally, to reduce the likelihood of fiberglass being present near the surface of the catalytic pre-preg, a woven fiberglass may be used with the inner pre-preg layers and a flat unwoven fiberglass may be used in the outer resin rich pre-preg layers. The combination of resin-rich pre-preg and flat unwoven fiberglass on the outer surface layer results in an exclusion zone of 0.7 mil (17 u) to 0.9 mil (23 u) between an outer surface and the encapsulated fiberglass. Glass styles 106, 1035, and 1067 are preferred for use on the outer resin rich surface since the glass fiber thicknesses are smaller (1.3-1.4 mil/33-35 u) than the glass fiber thickness found in typical pre-preg sheets with greater than 65% resin used in the central regions of the laminate, such as glass style 2116, which has 3.7 mil (94 u) fibers. These values are given as examples, the smallest glass fibers which are commercially available are expected to continue to reduce in diameter. The temperature vs. time plot 202 is tailored in the present invention to cause the catalytic particles and fiberglass to migrate away from the outer surface of the laminate, repelled by the surface tension of the epoxy during a liquid state of the gel point temperature. After the cooling cycle of plot 202, the cured C-stage pre-preg sheets are offloaded 114. The process which forms the cured C-stage pre-preg sheets may use single or multiple sheets of fiber fabric to vary the finished thickness, which may vary from 2 mil (51 u) to 60 mil (1.5 mm).

FIG. 3 shows a flowchart for the process of making pre-preg laminate with catalytic particles infused but excluded from the outer surface of the pre-preg. Step 302 is the blending of catalytic particles into the resin, often with an organic volatile added to lower the mixture viscosity, which forms the catalytic resin 106 placed in reservoir 108. Step 304 is the infusion of catalytic resin into the fabric such as rollers 104 of FIG. 1 may provide to form A-stage pre-preg, and step 306 is the initial rolling of catalytic resin infused fabric into B-stage pre-preg such as by rollers 110, step 307 is a baking step for removing organic solvents to form B-stage pre-preg, and step 308 is the pressing of catalytic resin infused fabric 130 into sheets of catalytic C-stage pre-preg in lamination press 126, which follows the temperature cycle of plot 202, with vacuum pump 128 evacuating chamber 124 throughout the lamination process to remove air bubbles from the epoxy and reduce any air voids that may form in the epoxy. The cooled finished catalytic C-stage pre-preg sheets are cut and stored for later use.

The FIG. 2 plot 202 of temperature vs. time shows the temperature profile of the pre-preg in the lamination press 112, which is critical for the formation of a catalytic pre-preg which has surface property of catalytic particles being excluded from the outer resin rich surface, but which are present just below the outer resin rich surface. The resin is in liquid state in reservoir 108, and the pre-preg is in in an A-stage after the resin is impregnated into the fiberglass and passes through rollers 110. The pre-preg is in a B-stage after baking 103 where the volatile organics are baked off accompanied by an initial resin hardening, which converts the B-stage pre-preg into becomes C-stage pre-preg at the end of the lamination cycle, such as the cooling phase of FIG. 2. The B-stage pre-preg is placed into the lamination press and a vacuum is pulled to prevent trapped air from forming between lamination layers. Heat is applied during a temperature ramp-up time 204 to achieve a temperature and pressure determined pre-preg gel point 205 for a duration on the order of 10-15 seconds (the gel point defined as the state where the liquid and solid states are close to equilibrium with each other), which is critical for the process of migrating the catalytic particles away from the surface, after which the temperature of the pre-preg is maintained at the dwell temperature and dwell time 206 which may be in the range of 60-90 minutes, followed by a cooling cycle 208. The dwell temperature and gel point temperature are pressure and resin dependent, in the example range of 120 C (for epoxy) to 350 C (for Teflon/polyimide resins). Maintaining the pre-preg at the gel point 205 for too short of a duration will result in the catalytic particles or fiberglass being undesirably present at the surface of the finished pre-preg.

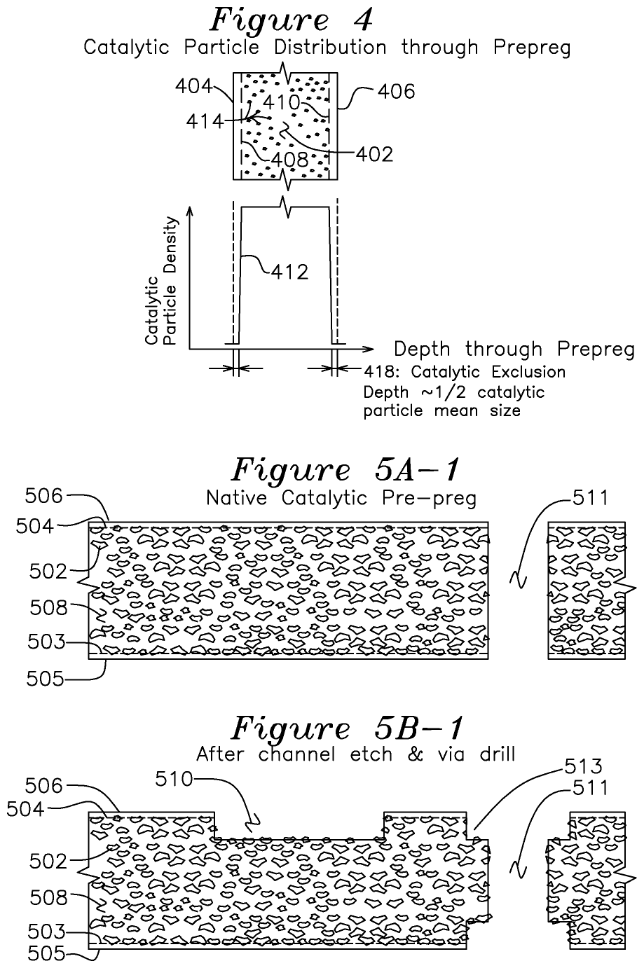

FIG. 4 shows the resultant catalytic pre-preg 402 formed by the process of FIGS. 1, 2, and 3, where the catalytic particles 414 are distributed uniformly within the central region of pre-preg 402, but are not present below a boundary region 408 below first surface 404, or below boundary region 410 below second surface 406. For the example particle distribution of particles smaller than 25 u, the catalytic particle boundary is typically 10-12 u below the surface (on the order of half of the particle size), accordingly this depth or greater of surface material must be removed for the embedded catalytic particles to be available for electroless plating.

In another example of the invention, the exclusion depth 418 is zero, with the catalytic particles exposed at the surface.

In another example of the invention, a non-catalytic laminate is used that does not contain catalytic particles, for which a surface treatment of catalyst is provided prior to electroless deposition.

One type of catalytic laminate has activated surfaces that must be masked to prevent unwanted electroless plating on the activated surface of the catalytic laminate. Another type of catalytic laminate with the catalytic particles below the surface is shown in FIG. 4, where the surface excludes catalytic particles in an exclusion depth which extends over the thickness extent from first surface 404 to first boundary 408, and from second surface 406 to second boundary 410, providing the benefit that a separate mask layer preventing contact with the catalytic particles is not required for electroless plating. Accordingly, removal of surface material from either first surface 404 to the exclusion depth of boundary layer 408 or deeper, or removal of surface material from second surface 406 to second boundary 410 exclusion depth, results in the exposure of catalytic material which may be used for electroless plating. The exclusion depth is desirable for a catalytic process which provides the resin rich surface to also exclude not only catalyst, but the fiber fabric, as removal of the surface layer in subsequent steps which results in the exposure of fibers which are difficult to ablate, requires additional cleaning steps, accordingly it is preferred that the surface removal be of resin only, so as to expose the underlying catalytic particles. This is accomplished by using a combination of resin-rich outer pre-preg layers and flat unwoven fiberglass layers having smaller diameter fibers on the outside layers.

A specific advantage of forming high density and fine linewidth traces in channels using electroless plating is that the traces are mechanically supported on three sides, which provides greatly improved trace adhesion to the dielectric laminate.

The sequence of FIGS. 5A-1 through 5J show example process steps for forming a circuit layer in a catalytic laminate. The figures show features which are drawn for clarity are not to scale to each other, and provide only a simplified view of the process steps for understanding the invention.

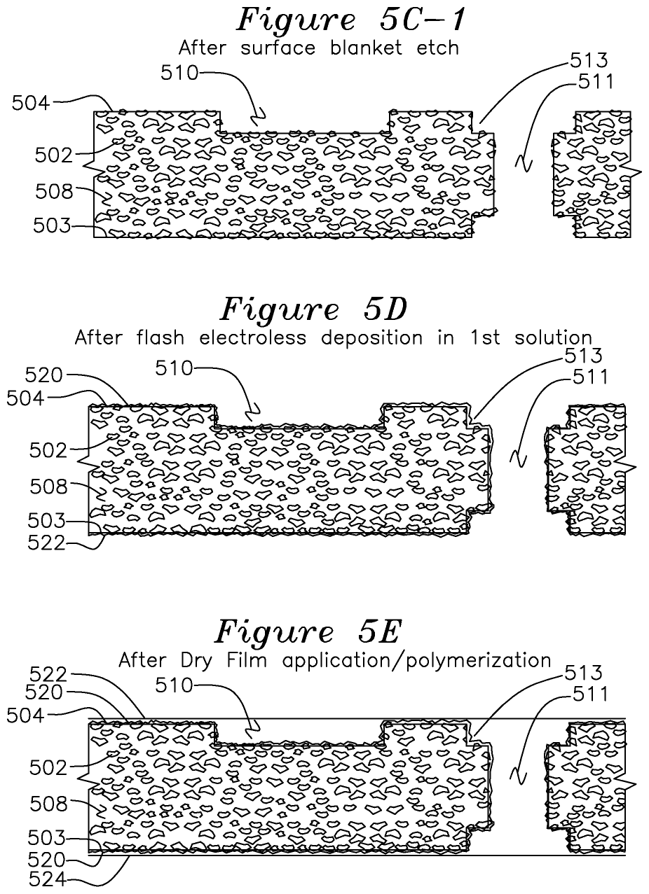

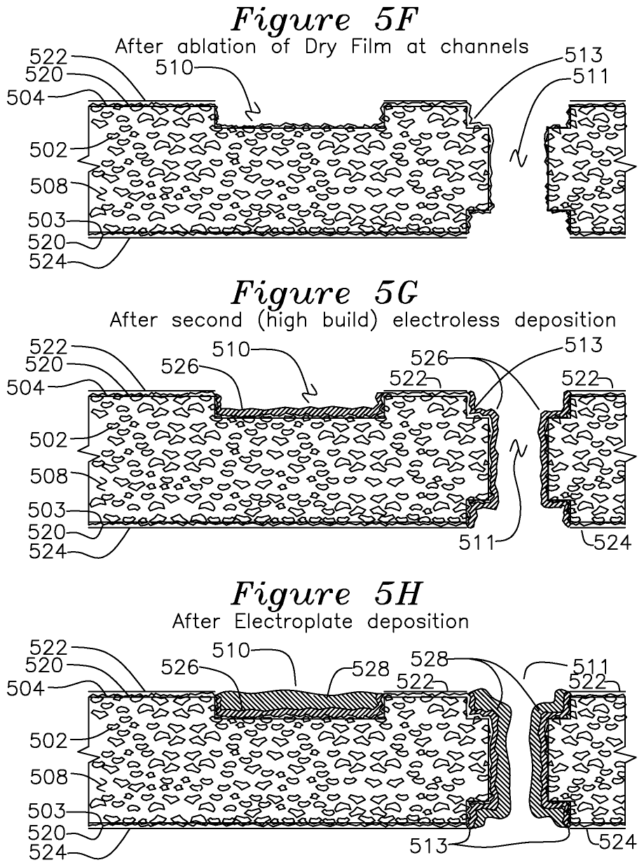

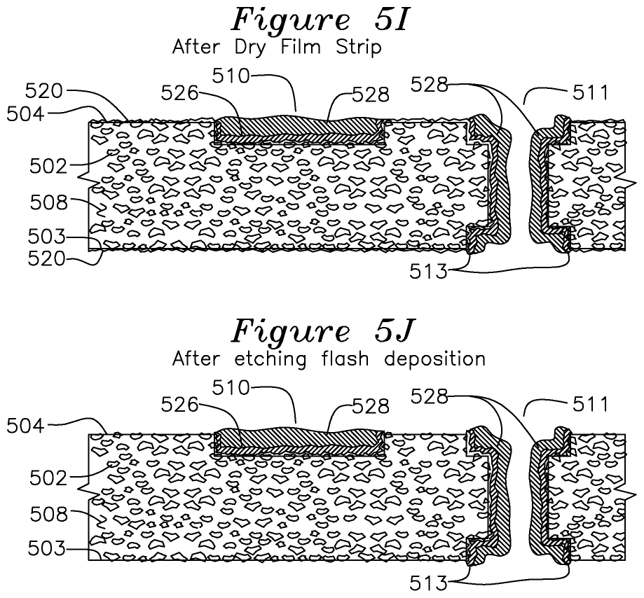

FIG. 5A-1 shows a magnified cross section view of catalytic pre-preg 508 formed by the process of FIGS. 1, 2, and 3. Catalytic particles 502 may be in the size range of 25 u and smaller, in the present example they are shown greatly magnified for clarity, but are typically in the range 12 u to 25 u, or have a majority of particles by count or size in that range. The catalytic particles may include heterogeneous catalytic particles (organic or inorganic particles having a catalytic surface coating) or homogeneous particles (catalytic metal particles), as described previously. For catalytic laminate with an exclusion depth for catalytic particles, the first boundary 504 is substantially 25 u below the first surface 506. The second surface 505 and second surface boundary 503 on the opposite surface are shown for reference, but may be formed in the same manner as described for the sequence of FIGS. 5A-1 to 5B-1. A drilled hole 511 which will provide connectivity between traces on the first layer 506 and traces on the second layer 505 is also shown.

FIG. 5B-1 shows the laminate of FIG. 5A-1 with a channel 510 formed by removal of the surface layer 506 in a region where a trace is desired. Pre-preg surface material is also removed in an annular ring 513 surrounding the via or through hole 511, the annular ring 513 including removal of prepreg surface material at the same or different depth as the trace channel 510. The removal of surface material may be by laser ablation, where the temperature of the catalytic pre-preg is instantly elevated until the catalytic pre-preg is vaporized, while leaving the surrounding pre-preg structurally unchanged, leaving the catalytic particles exposed. It is preferable to use a laser with a wavelength with a low reflectivity and high absorption of this optical wavelength for the pre-preg material being ablated, such as ultraviolet (UV) wavelengths. Examples of such UV lasers are the UV excimer laser or yttrium-aluminum-garnet (YAG) laser, which are also good choices because of the narrow beam extent and high available power which for forming channels of precise mechanical depth and with well-defined sidewalls. An example laser may remove material in a 0.9-1.1 mil (23 u to 28 u) diameter width with a depth governed by laser power and speed of movement across the surface. Another surface removal technique for forming channel 510 and annular ring 513 is plasma etching, which may be done locally or by preparing the surface with a patterned mask which excludes the plasma from the surface layers 506 or 505, such as a dry film photoresist or other mask material which has a low etch rate compared to the etch rate of catalytic pre-preg. The photoresist thickness is typically chosen based on epoxy/photoresist etch selectivity (such that plasma etch to the desired depth of removal of the cured epoxy leaves sufficient photoresist at the end of the etch), or in the case of photoresist which is used as an electroplate mask, the thickness is chosen according to desired deposition thickness. Typical dry film thickness is in the range of 0.8-2.5 mil (20-64 u). Plasmas suitable for etching the resin rich surface include mixtures of oxygen (O) and CF₄ plasmas, mixed with inert gasses such as nitrogen (N), or argon (Ar) may be added as carrier gasses for the reactive gases. A mask pattern may also be formed with a dry film mask, metal mask, or any other type of mask having apertures. Where a mechanical mask is used, the etch resist may be applied using any of photolithography, screen printing, stenciling, squeegee, or any method of application of etch resist. Another method for removal of the surface layer of pre-preg is mechanical grinding, such as a linear or rotational cutting tool. In this example, the pre-preg may be secured in a vacuum plate chuck, and a rotating cutter (or fixed cutter with movable vacuum plate) may travel a pattern defining the traces such as defined by x,y coordinate pairs of a Gerber format photo file. In another example of removing surface material, a water cutting tool may be used, where a water jet with abrasive particles entrained in the stream may impinge on the surface, thereby removing material below the first boundary 504. Any of these methods may be used separately or in combination to remove surface material and form channel 510 from pre-preg 508, preferably with the channel extending below the first boundary 504. Accordingly, the minimum channel depth is the depth required to expose the underlying catalytic particles, which is a characteristic of the cured pre-preg. As the catalytic material is dispersed uniformly through the cured pre-preg below the exclusion boundary 504, the maximum channel depth is limited by the depth of the woven fiber (such as fiberglass) fabric, which tends to complicate channel cleaning, as the fibers may break off and re-deposit in channels intended for electroless plating, or otherwise interfere with subsequent process steps. Typical channel depths are 1 mil (25 u) to 2 mil (70 u). The final step after removing the surface material to form the channel 510 is to clean away any particles of material which were removed, which may be accomplished using ultrasound cleaning, jets of water mixed with surfactant, or any other cleaning means which does not result in surface 506 material surrounding the channel from being removed.

In a preferred variation of the current invention, the catalytic particles reach the surface and no exclusion boundary 504 is present, with the channel 510 formed below the surface 506 as before, and only the catalytic particle distribution is modified to reach the surface in FIGS. 5A-1 and 5B-1.

A key advantage of electroless plating with channels etched in catalytic material is that the electroless plating progresses on all three sides at once, compared to electroplating which only progresses from the bottom (initially plated) layer.

FIG. 5C-1 shows a cross section view after a blanket plasma etch to reveal catalytic particles over the surfaces of the catalytic laminate which were previously below the exclusion depth of the catalytic laminate, such that all external surfaces of the catalytic laminate 508 have exposed catalytic particles. These exposed catalytic particles provide a scaffolding for flash electroless deposition 520 using a first high build electroless solution as shown in FIG. 5D.

FIG. 5E shows the application of a photoresist such as dry film 522 over the surface of the flash electroless deposition 520. In one example of the invention, the dry film spans the channels and apertures and remains in a substantially planar orientation, although adhesion to the flash electroless deposition 520 near to the surfaces where channels and via/through holes are formed is most important, as the unsupported spans of dry film 522 are patterned where channels and vias/through holes are formed, leaving the channels and vias exposed as shown in FIG. 5F. The patterning of photoresist or dry film 522 to provide for exposed channels may be performed any of several different ways, including by photolithographic techniques, mechanical removal, or optical ablation such as by patterning dry film or photoresist by using a laser to ablate the regions of photoresist covering the channels and holes, the laser operating at a lower power level which is suitable for removal of dry film compared to the higher power level used for forming channels in the catalytic laminate of step 5B-1.

FIG. 5G shows the application of a second (high build) electroless deposition 526, which forms over the flash electroless seed layer 520, and not where dry film 522 remains.

FIG. 5H shows the result of electroplate deposition, using the second electroless deposition 526 and first electroless deposition 520 operating as a cathode electrode providing a continuous electric potential over the surfaces to be plated, with the areas not to be plated remaining isolated by patterned dry film 522. Electroplating has the advantage of a higher density and lower porosity deposition, resulting in lower resistance traces than would be formed by only electroless deposition. Additionally, electroplated depositions which form the traces which remain at the end of the process have an etch rate which is much slower than electroless depositions which are used to form the continuous conductor which enables the electroplate depositions.

FIG. 5I shows the result of stripping the dry film 522, and FIG. 5I shows the result of etching flash electroless 520, resulting in the desired circuit board with high density interconnects, low trace resistance, and traces which are flush with the surface, providing stability during lamination of multiple circuit layers together to fabricate a multi-layer circuit board.

FIG. 5K shows a prior art etched copper trace for comparison purposes. Trace 554 is formed using a prior art subtractive etching process, where trace 554 is what remains after etching the rest of the copper which was present on a surface layer on non-catalytic pre-preg 550. The copper outer layer was patterned with a photoresist such as dry film and subsequently surface etched, which creates the trapezoidal section profile of trace 554 because the top of the trace experiences greater lateral etching than the bottom of the trace adjacent to the non-catalytic pre-preg 550. Another advantage of an additive process of the present invention is that for traces formed using a prior art process which etches all of the copper except the desired trace copper, surface contaminates on the surface cause adjacent trace shorting, as a copper bridge remains where the contamination was present on the surface of the copper, which does not occur in additive electroless plating of the present invention. For comparison with figure of the present invention, soldermask 552 is also shown. As seen in the figure, trace 554 is only supported by adhesion to substrate 550, whereas FIG. 5E trace 534 is supported on three sides, and is locked into its associated channel in the catalytic pre-preg 508.

In one variation of the process of FIGS. 5E, 5F, and 5G, the order of these steps may be rearranged such that following the flash electroless deposition of FIG. 5D, the second electroless deposition of FIG. 5G is performed to uniformly deposit high-build electroless copper 526 of the second solution inside and outside of the channel, covering the surface of flash electroless deposition. This would then be followed by the photoresist or dry film step of FIG. 5E, followed by patterning of the photoresist or dry film shown in step 5F (with both first and second depositions present in the channels and surfaces), followed by the electroplate of FIG. 5H. This reordering of patterning and second electroless deposition step has the flexibility of providing incremental additional protection of the flash electroless 520 in the channel 510, which is important where the patterning of the photoresistor dry film 522 results in erosion of the flash first electroless deposition 520 in the channel 510 during the patterning of the dry film in step 5F. In general, the flash first electroless deposition and second electroless deposition are copper depositions, which deposit with a grain size and porosity which is more open for electroless copper deposition than for subsequent electro-deposition which use the electroless depositions as a cathode electrode.

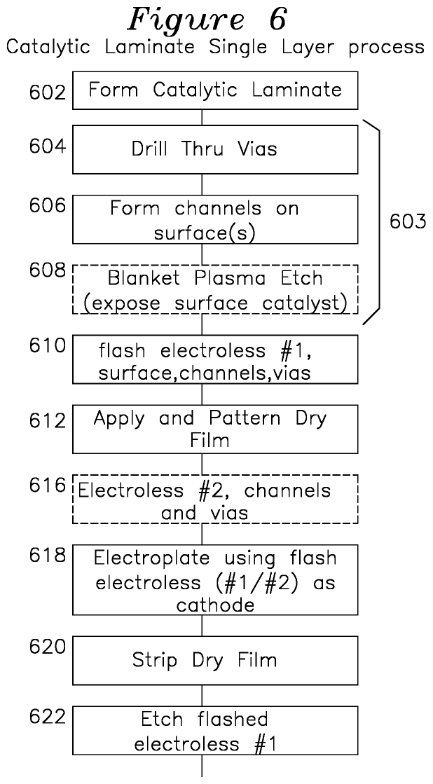

FIG. 6 shows example process steps for a catalytic laminate in step 602 either with an exclusion depth 418 as shown in FIG. 4 or with catalytic particles extending to the surface. Steps 604 drilling through holes and vias such as 511 of FIG. 5A-1 and step 606 forming channels having a channel depth shown as 510 in FIG. 5B-1 may be performed in any order. The blanket plasma etch step 608 corresponding to FIG. 5C-1 is only performed where the catalytic laminate has an exclusion depth 418 and catalytic particles are not exposed on the surface, which will be present after performing step 608. For catalytic laminate where the catalytic particles are sufficiently exposed on the surface to enable electroless deposition, step 608 may be skipped. Additionally, the order of the steps referenced in 603: drilling through holes or vias 604, forming channels 606, and optionally blanket plasma etching the surface to expose underlying catalytic particles (only performed if surface catalytic particles are not present) may be performed in any order.

Step 610 provides a first flash electroless deposition using a self-limiting electroless deposition solution and shown in FIG. 5D. Examples of a self-limiting flash electroless deposition solution includes Shipley/Dupont Circuposit 3350, which tend to self-limit with a published maximum deposition thickness of 0.35 mil and a published deposition rate of 0.5 micron (μm) (0.02 mil) per 10 minutes. This first electroless deposition has a load factor of 0.006 to 0.036 m²/L, operating temperature range of 33-43° C. in a mixture containing copper in the range 1.7-2.4 g/L, sodium hydroxide range of 7.0-8.0 g/L, formaldehyde range of 2.0-3.5 g/L, and Ethylenediamine tetra-acetic acid (EDTA) range of 35-25 g/L.

Step 612 shows the application of dry film over the surface, channels, and vias of the substrate, which is blanket coated over the surface of the substrate, channels, and vias/through holes, typically as a planar film in contact with the surface of the substrate and spanning the channels and vias/through holes and shown in FIG. 5E. The dry film may be blanket exposed to UV or other activation to polymerize and pattern the dry film into a durable surface. In step 614, the dry film is removed above the traces and vias/through holes to remove the bridged areas of dry film, thereby leaving only the vias/through holes and channels exposed, and the remaining surface areas coated by dry film, as shown in FIG. 5F. The laminate with exposed channels and vias/through holes are placed into a second electroless bath of step 616 with a high build solution such as Shipley/Dupont Circuposit 4500 with a published maximum build thickness of 1.5 mil, empirical maximum build thickness of 1.5 mil, load factor of 1.0 m²/L to 4 m²/L, an operating temperature range of 50-54° C. in a mixture containing copper in the range 1.5-3.0 g/L, sodium hydroxide range of 7.0-11.0 g/L, formaldehyde range of 2.8-3.8 g/L, and Ethylenediamine tetra-acetic acid (EDTA) range of 26-36 g/L.

Step 618 shows the electroplate process, whereby the electroless depositions of steps 610 and 616 provide a cathode electrode for the formation of deposition 510 shown in FIG. 5H. The dry film is stripped in step 620 corresponding to FIG. 5I and the flash deposition which was previously covered by dry film is etched to the substrate as shown in FIG. 5J, leaving the electroplate deposition 528, second electroless deposition 526, and only the underlaying flash deposition which provided the scaffolding for the second electroless deposition and electrode functionality in support of the electroplating deposition.

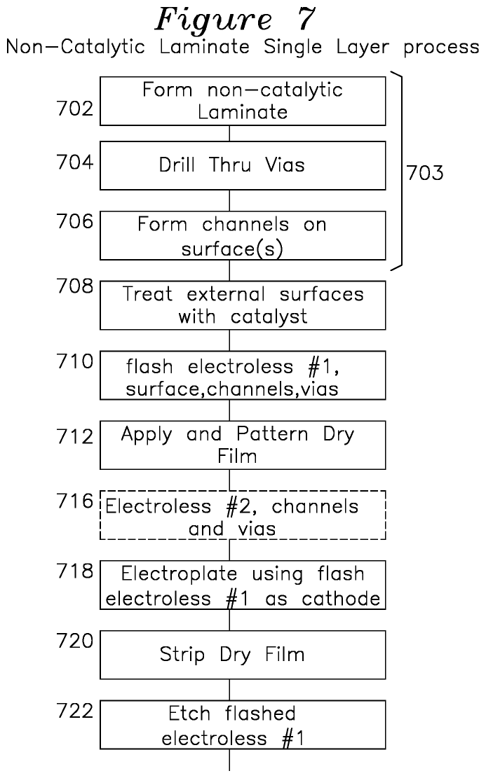

FIG. 7 shows a non-catalytic laminate process which is similar to the process of FIG. 6, but for a laminate that does not contain catalytic particles or catalytic powder. The non-catalytic laminate 702 has drilled vias or through holes 704, and channels (trenches) are formed on the surface in step 706. As before, the steps 702, 704, 706 may be performed in any order with respect to each other. The external surfaces are treated with a surface catalyst such as a Tin/Palladium bath or a commercial surface treatment such as the Direct™ Metallization Technology by Solution Technology Systems (www.solutiontechnologysystems.com) in step 708, which distributes catalytic particles on all of the surfaces of the laminate. The remaining process steps are similar to those of FIG. 6, including step 710 of flashing electroless deposition on all surfaces and vias and through holes for use in a subsequent electroplate which will serve as a cathode electrode for the electroplate process. Dry film step 712 involves attaching dry film photoresist to the surfaces of the laminate, after which the dry film covering the channels and through holes/vias is ablated using the laser 714. The exposed features of channels and annular ring around vias and through holes is ablated in step 714, followed by an optional electroless deposition in step 716 using the high build electroless solution described for step 618 of FIG. 6, followed by an electroplate step 718, using an exposed surface as a plating electrode. The dry film is stripped 720 and a quick etch is performed sufficient to remove the flash electroless of step 710. The optional electroless deposition step 716 may be performed using the second electroless deposition solution when it is desired to provide a greater deposition thickness than is provided by the flash electroless deposition of step 710.

For the methods of FIGS. 6 and 7, it is believed that the overall thickness of the electroless deposition of the flash deposition using the first solution (610/710) and second solution (616/716) preferably results in a deposition thickness on the order of 0.08 mil (2 μm) prior to the electroplate steps 618/718.

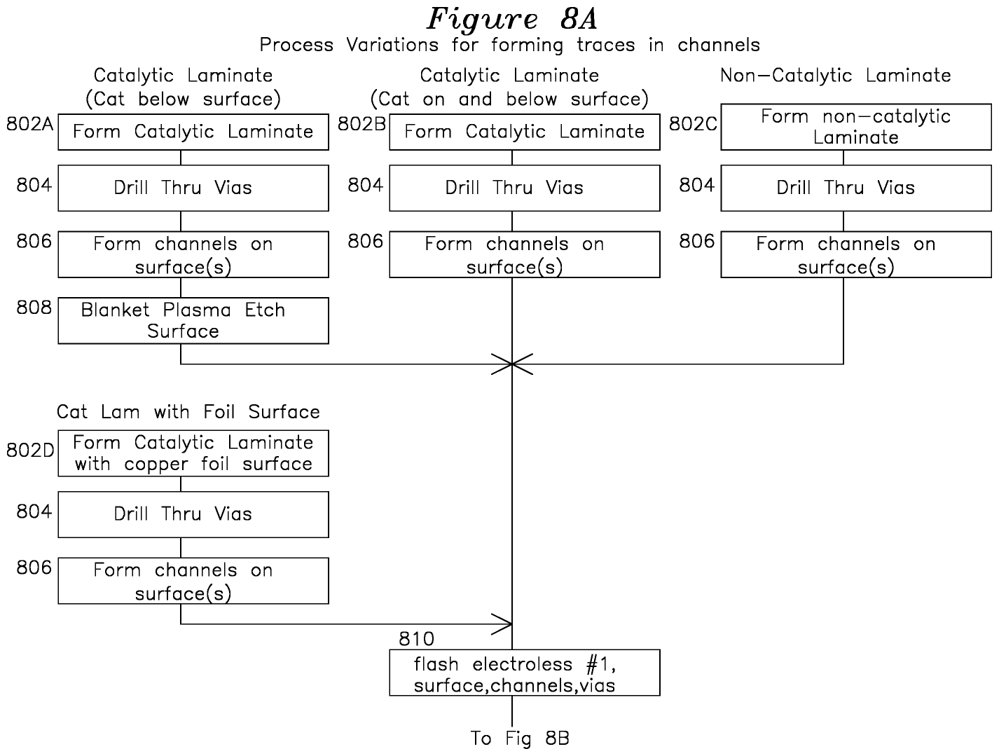

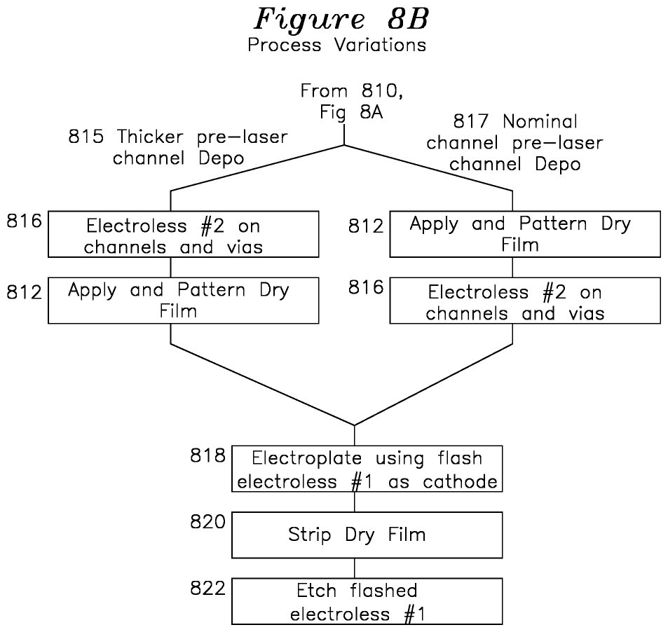

FIG. 8A shows a single process flow which incorporates many of the variations previously described with associated process flows. Identical reference numbers indicate the same step is performed, and a letter suffix indicates a variation of the process. A catalytic laminate which has the catalytic particles below the surface starts at process step 802A, a catalytic laminate with exposed surface catalytic particles starts at process step 802B, and a non-catalytic laminate starts at process step 802C. Drilling holes and vias 804 and forming channels step 806 as previously described are common to all materials, with the blanket plasma etch to reveal surface particles 808 performed only on the catalytic laminate 802A with catalytic particles below the surface, the plasma etch 808 causing those particles to be exposed at the surface of the catalytic laminate, as was shown in FIG. 5C-1. The common subsequent processing step 810 is the flash electroless deposition using the first electroless solution with self-limiting properties previously described. In another variation of the invention, a catalytic laminate with a foil surface may be used, as shown in the series starting with step 802D. The catalytic laminate has catalytic particles below the surface of the copper foil, such that forming channels which extend through the copper foil and into the catalytic laminate provide exposed catalytic particles for subsequent electroless copper deposition, as was described for 802A and 802B sequences. The copper foil may be of minimal thickness, such as on the order of 0.12 mil (3 μm) or less than 0.2 mil (5 μm). Drilling through vias 804 and channel 806 is performed as was previously described for the other variations of the invention.

The process continues after flash electroless deposition step 810 to the laminate surface, channels, and vias in FIG. 8B, and may bifurcate with respect to the order of patterning and second electroless deposition. Where the patterning may result in damage to the flash electroless deposition of the first deposition 520, or the photoresist is likely to strip in the presence of typical high PH levels associated with electroless deposition, processing path 815 provides for an unpatterned electroless deposition 816 over all of the flash electroless deposition prior to patterning step 812. The step of patterning the photoresist or dry film after application of the second electroless deposition reduces the likelihood of loss of flash electroless plating in the channels by increasing the thickness of the electroless deposition prior to the application of the dry film, at the expense of increasing the time required to etch away the first and second electroless deposition at the conclusion of the process.

In cases where the dry film patterning is unlikely to harm or erode the flash electroless deposition 520 in the channel 510 sufficient to interfere with electrodeposition, the processing steps of 817 are used, where the photoresist or dry film 522 is applied in step 812, followed by electroless deposition using the high build second solution in step 816, such that the high build second electroless solution results in deposition only inside the channels.

The subsequent steps 818, 820, and 822 are common to all variations of the process, electroplating 818 using the first and/or second electroless deposition as the cathode electrode, followed by stripping the dry film 820, and a final etch to remove the flash electroless (for path 817), or to remove the flash electroless and overlaid second electroless deposition of path 815.

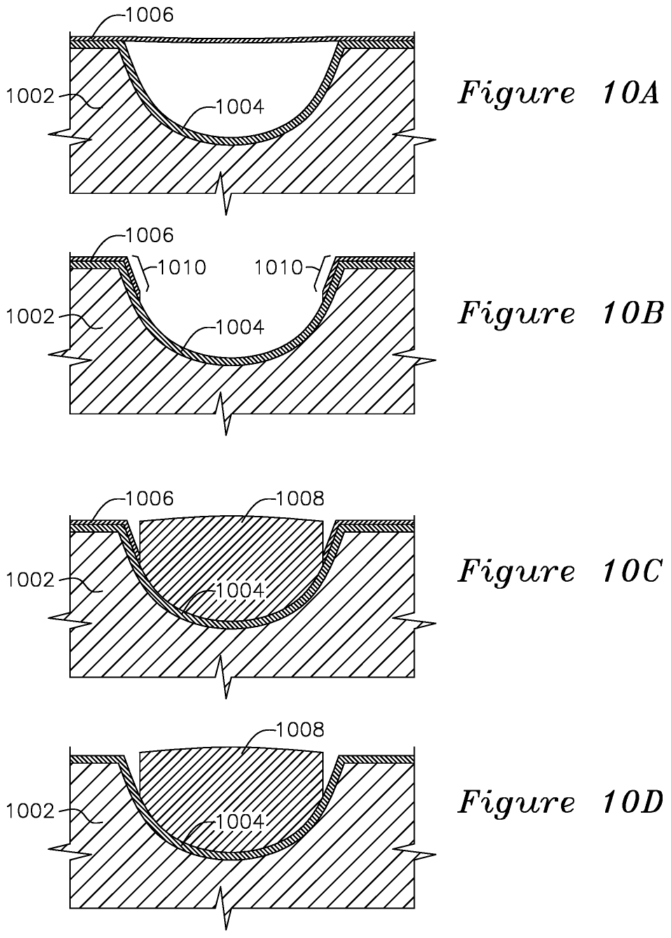

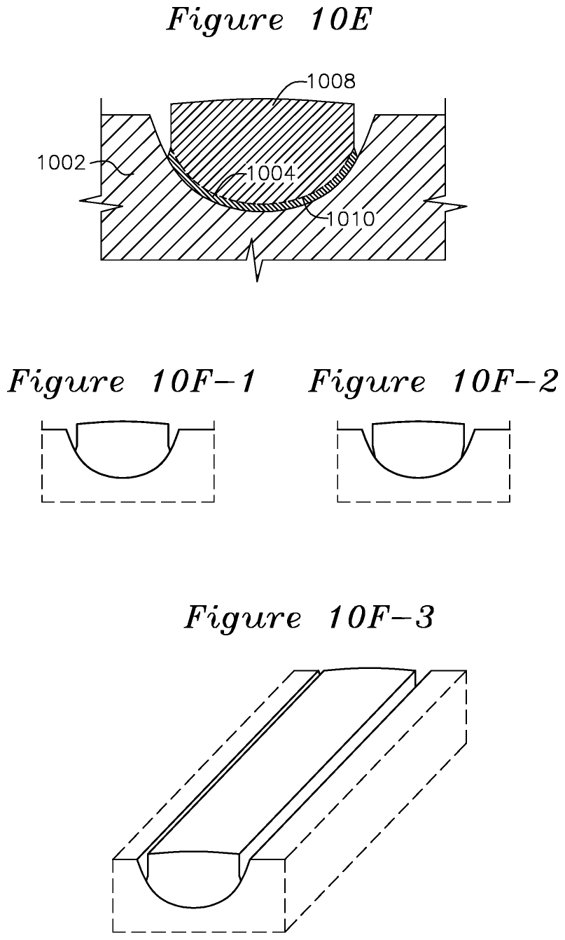

As can be seen in FIG. 5J, upon completion of the steps of the process according to the various fabrication examples of FIGS. 8A and 8B, the circuit board laminate 508 includes a laser-ablated channel 510, an inner flash deposition of first electroless deposition 520 overlaid by a second electroless deposition 526, overlaid by electroplated copper 528. This creates a distinctive cross section characteristic, where the flash first deposition 504 is a self-limiting electroless deposition such as Shipley 3350, the flash first deposition having a thickness on the order of a nominal 0.08 mil (2 μm) or in the range from ½ to 2× the nominal 0.08 mil flash first deposition thickness, and a second deposition 526 thickness sufficient to prevent loss of electroless depositions 520 and/or 526 sufficient to prevent localized electroless plating on an exposed electroless deposition region following dry film pattern step 812. The combined thickness of the flash first electroless deposition and second electroless deposition is on the order of a nominal 0.150 mil (4 μm) or in the range of ½ to 2× the nominal 0.150 mil. The electroplated deposition 528 thickness can be any range which extends from the first electroless deposition or second electroless deposition to the surface of the laminate. The flash first electroless deposition 520, second electroless deposition 526, and electroplate deposition 528 each have different microscopic physical characteristics such as copper grain size, porosity, and boundary. A cross section of the resulting trace in the laminate such as FIG. 5J may indicate lower or greater electroless deposition grain size between the flash electroless deposition and second electroless deposition, and the electrodeposition will have denser packing of deposition grains. Additionally, since the flash first deposition is self-limiting, a boundary may form in the interface between the flash first deposition and second deposition. Other conductive metals may be used, but in the present example, the resulting channel fabrication has conductive traces formed in channels, the conductive traces comprising a first applied electroless copper deposition which is overlaid by an electroplated copper using the electroless copper as a cathode electrode. This creates a trace, when viewed in cross section, has specific unique properties also described for FIG. 10E. The electroplated layer will have better conductivity by a factor of approximately 2×. When subjected to an acid solution, the electroless copper etches at two to three times the etch rate of an electroplate deposition.

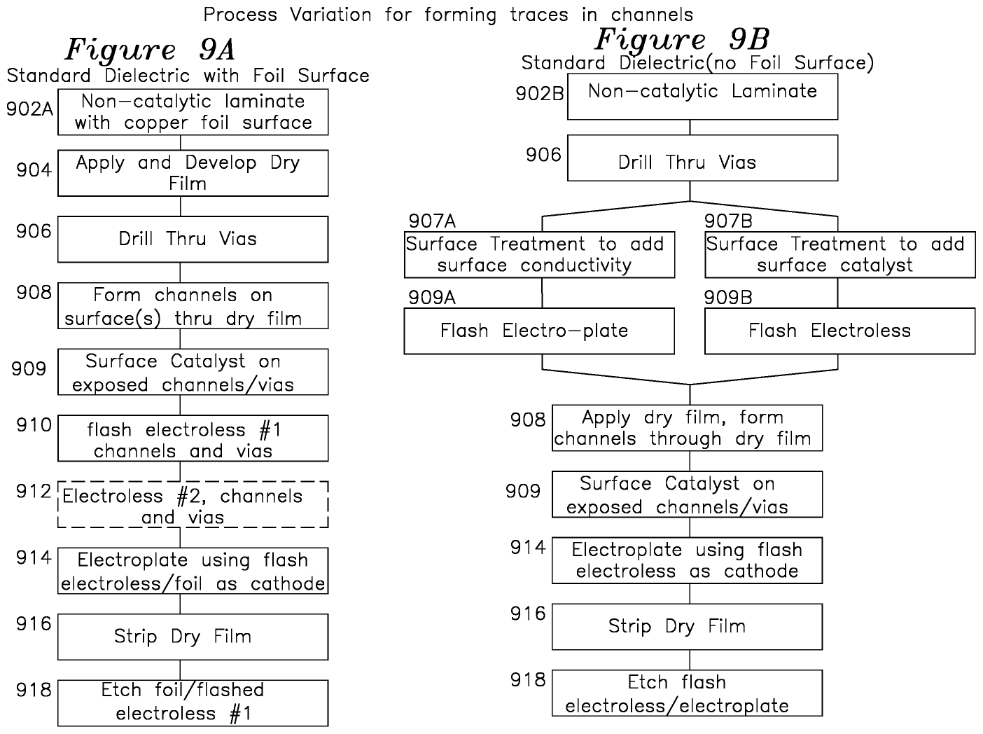

FIGS. 9A and 9B show two additional variations of the process which provide for a single channel formation step combined with ablation of the photoresist. In cases where only the photoresist is to be ablated such as by laser, the power level is significantly lower than where the photoresist and channel are both ablated in a single patterning and channel formation step. Step 902A starts with a non-catalytic laminate with a thin copper foil applied to at least one surface of the non-catalytic laminate, such as a copper foil less than 3 μm thick. Dry film is applied and field developed to create a continuous resist layer over the copper surface in step 904. Vias and through holes are drilled 906, followed by formation of channels where traces are desired in step 908, the channels having a depth through the thin copper foil and into the dielectric with a channel depth as required in step 908. A catalytic surface treatment is performed in step 909 as is required for non-catalytic dielectric, followed by a flash electroless deposition also performed in step 910, which deposits electroless copper on the inner surface of vias and trace channels formed in step 908, but not on the patterned dry film where channels are not present. An optional second electroless step 912 is performed, if needed, to increase the thickness of the electroless deposition in the channels and vias, otherwise, the electroplate step 914 is performed which uses the previously applied laminate copper foil in step 902A and subsequently applied electroless copper of 910 and optional step 912 as a cathode electrode for the electroplating process. The electro-plating forms a dense copper deposition on the exposed traces and vias/apertures, and the single pass of forming the channels and application of dry film provide the benefit of fewer passes through the laser ablation process. The subsequent steps of stripping the dry film 916 and etching the dielectric foil 918 or other conductor previously concealed under the dry film (now removed) are performed. At this point, the circuit board has fine pitch traces embedded in the conductive channels in the surface and may be subsequently laminated to other dielectrics with trace layers to form multi-layer circuit boards, or it may be used in its current state as a circuit board.

FIG. 9B shows an alternative process for a standard dielectric with no foils in step 902B. Where a process step is identical to the one described in FIG. 9A, the same reference number is used. Following step 902B, vias and through holes are drilled in subsequent step 906, followed by providing a flash conductive layer of steps 907A or 907B, which describe alternative methods for forming the flash layer, either using a quick (flash) electroplating in steps 907A/909A, or flash electroless deposition in steps 907B/909B. The sequence of 907A and 909A describe a flash electroplating process, whereby a semi-conductive surface such as fine carbon is applied 907A to a surface of the non-catalytic laminate, and an electroplating process 909A is performed for only long enough to generate a conductive copper surface which will support a subsequent electro-plating process of step 914. Alternatively, steps 907A/907B provide a flash deposition layer of electroless copper deposition, using a surface catalytic treatment 907B followed by flash electroless deposition 909B. After the flash deposition of step 909A/909B is applied, dry film is applied and cured over the entire surface of the laminate. Channels and vias are formed in step 908, followed by the surface catalyst of step 909 applied to the exposed channels and areas where dry film was ablated, followed by standard electroplating 914 which uses the previously applied flash layer for a cathode electrode, followed by the previously described steps of stripping the dry film 916 and etching the flash layer in step 918.

When ablation is used for forming channels and patterning, certain physical characteristics of the trace may be observed. FIG. 10A shows a cross section view of catalytic or non-catalytic substrate 1002 which has an electroless deposition 1004 covering the substrate in channel areas and unchanneled top surface areas, and an unpatterned dry film 1006 applied, corresponding to any of the previously described methods. FIG. 10B shows the cross section after patterning such as by ablation of the dry film, the dry film 1006 has a heat effected zone 1010 where dry film 1006 conforms to the electroless deposition 1004. FIG. 10C shows the electroplate deposition 1008, using electroless flash deposition 1004 as a cathode electrode for the process. FIG. 10D shows the next step in the sequence, where the cross section view has the dry film removed 1006 according to any of the well-known methods for stripping dry film. FIG. 10E shows the final cross section of the trace at the end of the process, where substrate 1002 has a copper conductor formed by electrodeposited copper overlaying the electroless copper 1004, with a boundary 1010 which is only detectable by metallurgical and physical examination of the difference in properties between electroless deposition region 1004 and electroplate region 1008. The depositions of electroless and electroplating result in copper forming in grains with distinctive physical properties. Electroless copper depositions have a grain structure which is loosely consolidated and more porous than electroplated copper depositions. Accordingly, electroless depositions 1004 of the present invention have a higher bulk resistivity compared to electroplate depositions 1008, as well as an etch rate which is approximately two to three times greater for electroless deposition than for an electroplated deposition. An additional physical characteristic is that a boundary 1010 may be visible between the electroless 1004 and electroplate 1008 depositions.

FIGS. 10E-1 and 10E-2 are example line drawings of a cross section appearance of the channel, and FIG. 10E-3 is a perspective view of a conductor in a channel shown in cross section views 10E-1 and 10E-2.

The preceding description is only to provide examples of the invention for understanding the underlying mechanisms and structures used, and is not intended to limit the scope of the invention to only the particular methods or structures shown. For example, the sequences of FIGS. 5A-1 and 5J show a single sided construction with the trace channels cut on first surface only, whereas the same structures and methods can be applied to the second surface 505 without loss of generality, as the electroless plating step can be applied to channels or exposed catalyst on both sides of the board in a single step. Additionally, layers fabricated as in FIGS. 5B-1 can be formed on individual layers which are subsequently laminated together into a single board with mixed layers of catalytic pre-preg and non-catalytic pre-preg, and the scope of claims related to “multilayer PCB” are to be interpreted to include such constructions. Similarly, although the trace structure and via structures shown are examples for illustration, and are not intended to limit the invention to these constructions. For example, a mounting hole for a through hole component with no electrical connection could be formed without a connecting trace or annular ring according to the novel aspects of the process.

In the case where the processes of FIG. 9A or 9B are used, patterning the resist and forming the channels in a single step 908, the end result shown in FIG. 10E remains accurate, where only the electroless deposition 1010 below electroplated trace 1008, although the FIGS. 10A to 10D are not representative, since the dry film 1006 ablation and channel are formed in a single step.

In the present specification, “approximately” a nominal value is understood to mean within a range of ¼th the nominal value to 4 times the nominal value, “substantially” a nominal value is understood to mean in the range of ½ the nominal value to 2 times the nominal value. “Order of magnitude” of a nominal value is understood to be the range from 0.1 time the nominal value to 10 times the nominal value.

Certain post-processing operations are not shown which are generic to printed circuit board manufacturing, and may be performed using prior art methods on boards produced according to the novel process. Such operations include tin plating for improved solder flow, gold flash for improved conductivity and reduced corrosion, soldermask operations, silkscreening information on the board (part number, reference designators, etc.), scoring the finished board or providing breakaway tabs, etc. Certain of these operations may produce improved results when performed on planarized boards of certain aspect of the present invention. For example, silkscreened lettering over traces or vias traditionally breaks up because of trace and via thickness over the board surface, whereas these operations would provide superior results on a planarized surface.

We claim:

1. A process for forming a catalytic laminate with traces, the process comprising:
drilling through vias and forming channels on at least one surface of a catalytic laminate, the inner surfaces of the through vias and channels and surfaces having catalytic particles exposed;
performing a flash electroless deposition using a first solution with a self-limit for deposition, the flash electroless deposition providing a deposition on the inner surfaces of the through vias, the channels, and the surfaces;
applying a photoresist to the surfaces of the laminate, the photo resist also covering the through vias and the channels;
ablating the photoresist above the through vias and the channels;
performing an electroless deposition using a second solution with high build, the electroless deposition providing a deposition over the flash electroless deposition on the vias and channels;
performing an electro deposition by connecting a surface of the laminate as a cathode in an electroplating bath;
stripping the dry film;
etching the flash electroless deposition.

2. The process of claim 1 where the photoresist is a dry film.

3. The process of claim 9 where the first solution comprises a mixture containing copper in the range 1.7-2.4 g/L, sodium hydroxide range of 7.0-8.0 g/L, formaldehyde range of 2.0-3.5 g/L, and Ethylenediamine tetra-acetic acid (EDTA) range of 35-25 g/L.

4. The process of claim 1 where the second solution comprises a mixture containing copper in the range 1.5-3.0 g/L, sodium hydroxide range of 7.0-11.0 g/L, formaldehyde range of 2.8-3.8 g/L, and Ethylenediamine tetra-acetic acid (EDTA) range of 26-36 g/L.

5. The process of claim 3 where the first solution has a temperature in the range 33-43° C.

6. The process of claim 4 where the second solution has a temperature in the range 50-54° C.

7. The process of claim 6 where ablating the photoresist is laser ablation.

8. The process of claim 9 where the dry film is planar.

9. The process of claim 12 where the dry film is polymerized after application as a planar layer.

10. The process of claim 15 where the catalytic laminate has catalytic particles an exclusion depth below a surface, and forming channels includes a surface etch to expose the catalytic particles.

11. A process for forming a circuit layer with traces on a laminate, the process comprising:
drilling through vias and forming channels on at least one surface of the laminate;
performing a surface treatment providing catalytic surfaces on the vias, channels, and the at least one surface of the laminate;
performing a flash electroless, the flash electroless deposition providing a deposition on the inner surfaces of the through vias, the channels, and the surfaces;
applying a photoresist to the surfaces of the laminate, the photo resist also covering the through vias and the channels;
ablating the photoresist above the through vias and the channels;
performing an electroless deposition over the flash electroless deposition on the vias and channels;
performing an electro deposition by connecting a surface of the laminate as a cathode in an electroplating bath until a conductive trace is formed in a channel;
stripping the dry film;
etching the flash electroless deposition.

12. The process of claim 11 where the photoresist is a dry film.

13. The process of claim 11 where the first solution comprises a mixture containing copper in the range 1.7-2.4 g/L, sodium hydroxide range of 7.0-8.0 g/L, formaldehyde range of 2.0-3.5 g/L, and Ethylenediamine tetra-acetic acid (EDTA) range of 35-25 g/L.

14. The process of claim 10 where the second solution comprises a mixture containing copper in the range 1.5-3.0 g/L, sodium hydroxide range of 7.0-11.0 g/L, formaldehyde range of 2.8-3.8 g/L, and Ethylenediamine tetra-acetic acid (EDTA) range of 26-36 g/L.

15. The process of claim 16 where the first solution has a temperature in the range 33-43° C.

16. The process of claim 19 where the second solution has a temperature in the range 50-54° C.

17. The process of claim 11 where ablating the photoresist is laser ablation.

18. The process of claim 12 where the dry film is planar.

19. The process of claim 6 where the dry film is polymerized after application as a planar layer.

20. A process for forming a circuit layer in a laminate, the process comprising:
drilling through vias on at least one surface of the laminate;
performing a surface treatment providing catalytic surfaces on surfaces of the vias and the at least one surface of the laminate;
performing a flash electroless deposition, the flash electroless deposition providing a deposition on the surfaces of the vias and on the surface of the laminate;
applying a photoresist to a surface of the flash electroless deposition, the photoresist also covering the through vias and the channels;
ablating the photoresist above the through vias and also forming exposed channels and exposed vias in the laminate below the ablated photoresist;
performing a surface treatment providing catalytic surfaces on the exposed channels and exposed vias;
performing an electroless deposition, the electroless deposition providing a deposition over the exposed channels and exposed vias;
performing an electro deposition by connecting a surface of the laminate as a cathode in an electroplating bath;
stripping the dry film;
etching the surface flash electroless deposition.

21. A process for forming a circuit layer in a laminate having a thin surface foil, the process comprising:
drilling through vias on at least one surface of the laminate;
applying a photoresist to a surface of the laminate;
ablating the photoresist in a pattern, ablating the photoresist including areas where channels are formed below the copper foil and into the laminate;
performing a surface treatment providing catalytic surfaces on the channels and exposed vias;
performing an electroless deposition, the electroless deposition providing a deposition over the exposed channels and exposed vias;
performing an electro deposition by connecting a surface of the laminate as a cathode in an electroplating bath;
stripping the dry film;
etching the surface flash electroless deposition.
